(19) United States
(12) Patent Application Publication
(10) Pub. No.: US 2006/0210000 A1
(43) Pub. Date: Sep. 21, 2006

(54) Communication system, communication unit and method of sharing a communication resource

(76) Inventor: Howard Thomas, Cirencester, Glos (GB)

Correspondence Address: MOTOROLA, INC., 1303 EAST ALGONQUIN ROAD, IL01/3RD, SCHAUMBURG, IL, 60196, US

(21) Appl. No.: 10/573,008

(22) PCT Filed: Sep. 2, 2004
(86) PCT No.: PCT/EP04/52001

§ 371 Date: Mar. 21, 2006

(30) Foreign Application Priority Data
Oct. 4, 2003 (GB) 0323250.1

(51) Int. Cl. H03D 1/04

(52) U.S. Cl. 375/346

(57) ABSTRACT

A wireless communication system (200) comprises one or more communication networks supporting communications for a plurality of communication units on a shared communication resource. An identification function (144) identifies interference within, or non-availability of, a portion of the shared resource; and a communication adaptation function (142), responsive to a resource-responsible agent (140) that is triggered when interference is identified, reduces a level of interference or makes a portion of the shared resource available for use. A communication unit and a method of sharing a communication resource are also provided. In this manner, a mechanism identifies and targets those resource irresponsible users for automatic adjustment of their performance attributes to minimise interference in one or more communication networks.

### FIELD OF THE INVENTION

This invention relates to an efficient method for sharing a communication resource and, in particular, to a mechanism to share a communication resource in a communication system having a number of uncoordinated networks.

### BACKGROUND OF THE INVENTION

In the field of this invention it is known that radio frequency resource is both scarce and expensive. Hence, in designing and operating cellular-based systems, spectrum efficiency must be optimised. This is critical, particularly in the current wireless communication climate, where several Operators compete for customers within the same frequency band. In current communication systems, a number of known spectrum allocation techniques exist.

One known spectrum allocation technique is to allocate a fixed amount of spectrum in a particular communication system to each Operator. The Operators are committed to fulfil certain objectives in terms of the amount of traffic they service and the coverage area they support. If the Operators do not fulfil these objectives, part of their spectrum may be reallocated to other Operators in need of such spectrum.

However, this approach has the disadvantage that the assessment of whether the objectives are met, and fixedly re-allocating spectrum if they are not met, takes weeks if not months to implement. Furthermore, the technique is generally accepted as too inflexible to meet its desired purpose. Notwithstanding this, it is also clearly unsuitable if the spectrum usage for particular Operators occurs in peaks and troughs. A more dynamic way of reallocating spectrum according to traffic needs is therefore required.

An alternative technique has been proposed in U.S. Pat. No. 5,907,812, which focuses on utilisation of unused spectrum. U.S. Pat. No. 5,907,812 attempts to optimise spectrum utilisation by providing for flexible coexistence of several radio systems on a common radio frequency band. This involves searching for frequencies that satisfy the interference requirements (in terms of influences from neighbouring Operator frequencies) and the service requirements (in terms of bandwidths required) of the communication system. This scheme is similar to “Dynamic Carrier (Spectrum) Assignment (Allocation)” between co-existent and collaborative Operators. In such a scheme, all frequencies are “pooled” and are made available to all Operators, provided they comply with defined allocation criteria. In effect, such schemes support “spectrum sharing”, which is becoming a more acceptable approach to maximise the use of the limited resource.

In a mobile radio communication system the process of allocation of resources to mobile/subscriber users involves several different functions. In a first instance, when a mobile/subscriber user requests service from the mobile radio network, a call admission process is used to decide if the call will be admitted or not. In a wideband code division multiple access (WB-CDMA) system this decision is made in a radio network controller (RNC) and is based on the available resources in the accessed cell and factors such as the service requested and the priority level of the call. After a call is admitted to the system, the Medium Access Control (MAC) layer makes decisions in the RNC about scheduling resources for that call dependent upon the available resources in the cell and service type—e.g. constrained delay data or ‘best-effort’ data. As the RNC scope extends over a number of cells, the RNC may make partially centralised decisions about resource allocation.

In some communication networks there may be a multiplicity of frequency bands or systems to which a call may be allocated. In these circumstances it is possible to have a centralised approach to resource allocation whereby a central node acquires traffic load information on a number of the frequency bands and makes a decision considering all possible bands to place the call. Therefore, in a cellular system, there is an implicit trade-off between the amount of information that is exchanged between cells, the time taken to transfer that information, the resources used to transfer that information, and the accuracy and timeliness of the assignment decisions.

An alternative strategy is to use a distributed process to allocate the resources to the users. This strategy reduces the overhead and perhaps facilitates more timely, if less accurate, decisions. However, this strategy relies on the assumption that all nodes in the network use the same algorithm, so that a fair allocation of resources is achieved.

However, in an uncoordinated scenario, such as itinerant frequencies for PMR applications, wireless local area networks (LANs) such as 802.11b and Bluetooth™, the digital European cordless telephone (DECT) standard, or other ad-hoc shared-spectrum networks, it is not possible to collate resources centrally. In effect, mobile stations (MSs) or base transceiver stations (BTSs) on one system have no knowledge of interference that they are causing to MSs/BTSs on the other system. Also, in practice, it is highly unlikely, if not impossible, to ensure that the same resource allocation strategy is applied at all distributed nodes. Such systems typically operate using dynamic channel methods that select a channel for operation depending on the level of interference measured on that channel. As such, these systems do not enable fair access to the available communication resources for each system sharing the resource—that is one system may so degrade the quality of the other to effectively prevent another from operating. Also, the problems associated with the co-existence of dissimilar systems are not addressed.

Thus, there exists a need in the field of the present invention to provide a communication system and a method of sharing a communication resource that encourages a fair allocation of resources, particularly in an uncoordinated network scenario, wherein the abovementioned disadvantages may be alleviated.

### STATEMENT OF INVENTION

In accordance with a first aspect of the present invention there is provided a communication system. The communication system comprises one or more communication networks supporting communications for a plurality of communication units on a shared communication resource. An identification function identifies an interference within, or non-availability of, a portion of the shared resource. A resource-responsible agent is responsive to the identification of an interference within, or non-availability of, a portion of the shared resource and a communication adaptation function, responsive to the resource-responsible agent reduces a level of interference or makes available a portion of the shared resource available.

In accordance with a second aspect of the present invention there is provided a communication unit. The communication unit comprises a processor operating on a shared communication resource. The processor comprises a resource-responsible agent, which is responsive to an identification of interference within, or non-availability of, a portion of the shared communication resource. A communication adaptation function, responsive to the resource-responsible agent reduces a level of interference caused by the communication unit or makes a portion of the shared resource available for use by other communication units.

In the provision of a resource-responsible agent, which is activated or distributed in response to interference or a lack of availability of a communication resource, sharing of communication resources is made feasible, particularly in an uncoordinated network scenario. Advantageously, by providing interference control measures to those users whose behaviour is adversely affecting other users, results in better utilisation of the available shared communication resource. In addition, the mechanism provides flexible spectrum sharing and an increase in spectrum efficiency.

A particular feature of the preferred embodiment of the present invention is the identification of and targeting of resource irresponsible users for automatic adjustment of their performance attributes. In this manner, the mechanism can also be used to alter long-term behaviour of subscribers that interfere with each other. In effect, the mechanism promotes, and to some degree enforces, ‘co-operative’ behaviour between subscribers and/or networks.

In accordance with a third aspect of the present invention there is provided a reconciliation and mediation agent. The reconciliation and mediation agent is operably coupled to, and mediates between, at least two interfering uncoordinated networks

The use of a reconciliation and mediation agent provides more flexibility in the adjustment of resources available to each network or communication unit(s) operating within a shared resource network.

In accordance with a fourth aspect of the present invention there is provided a resource-responsible agent.

The resource-responsible agent is distributable to a subscriber communication unit or wireless communication network to effect a modification of the subscriber communication unit's or communication network's operational capabilities in response to a trigger related to potential interference or non-availability of a communication resource.

Advantageously, the proposed mechanism to use a readily distributable/activatable resource-responsible agent allows decentralized control of a network. The resource-responsible agent can be pre-programmed into communication units, with ‘good’ behaviour placing the agent and its effect on the subscriber's/BTS's behaviour in remission. The activation of the resource-responsible agent may be configured to be sensitive to a number of parameters, not least including one or more of the following: location, frequency, power, spreading factor, interference caused or its probability, service type.

The effect of the resource-responsible agent on the behaviour of the subscriber units and/or networks may be time limited, causing temporary reduction in service levels, chance of call set up, or permitted power levels. Furthermore, the resource-responsible agent or its activation may be distributed between various communication units, e.g. between mobile subscriber units, base transceiver stations, fixed network subscribers.

In accordance with a fifth aspect of the present invention there is provided a communication unit. The communication unit comprises a processor to receive a resource-responsible agent. The processor modifies one or more operational parameters of the communication unit in response to determining that it is operating in a resource irresponsible manner.

In accordance with a sixth aspect of the present invention there is provided a method of sharing a communication resource in a communication system. The communication system comprises one or more networks supporting communication for a plurality of communication units on the shared communication resource. The method comprises the step of identifying an interference within or non-availability of a portion of the shared resource. The method further comprises distributing and/or activating a resource-responsible agent to reduce a level of interference or make a portion of the shared resource available for use in the wireless communication system in response to identifying interference within or non-availability of a portion of the shared resource. One or more communication functions of the communication unit is/are adapted upon receipt of, or activation of, the resource-responsible agent.

### BRIEF DESCRIPTION OF THE DRAWINGS

Exemplary embodiments of the present invention will now be described, with reference to the accompanying drawings, in which:

FIG. 1 shows an overview block diagram of a wireless communication unit adapted in accordance with a preferred embodiment of the invention;

FIG. 2 shows a simplified block diagram of a wireless communication system supporting multiple technologies/networks, in accordance with a preferred embodiment of the invention; and

FIG. 3 is a flow chart illustrating a mechanism for propagating and utilising a resource-responsible agent, in accordance with a preferred embodiment of the invention.

### DESCRIPTION OF PREFERRED EMBODIMENTS

In summary, the preferred embodiment of the present invention provides a framework within which the MSs/BTSs on one network can determine whether they are being ‘resource-responsible’ and, if they are not operating in a resource-responsible manner, a mechanism is provided to automatically and autonomously adapt one or more operational parameters to make them operate in a more resource-responsible manner. In accordance with a preferred embodiment, a resource-responsible agent is employed to provide a mechanism to enforce responsible behaviour. If the resource-responsible agent is already installed in the resource-irresponsible communication unit, it may be activated upon receipt of a trigger. If the resource-responsible agent is not already installed in the resource-irresponsible communication unit, it is forwarded to the resource-irresponsible communication unit, which adapts one or more of its operational parameters in response to the receiving resource-responsible agent.

It is envisaged that the activation of the resource-responsible agent may be triggered by, for example, location data, cell identification data, data communicated from one or more other networks or from some “reconciliation agent”, operably coupled to, or located in, the communication system.

The resource-responsible agent may be introduced into any single network, such as an un-coordinated network, for example to provide a mechanism for self-control of the resource usage by users within the network. Alternatively, it is envisaged that the resource-responsible agent may be introduced into any multiple technology communication system, where different communication units supported from one or more of a number of networks compete for or are allocated a portion of a shared communication resource.

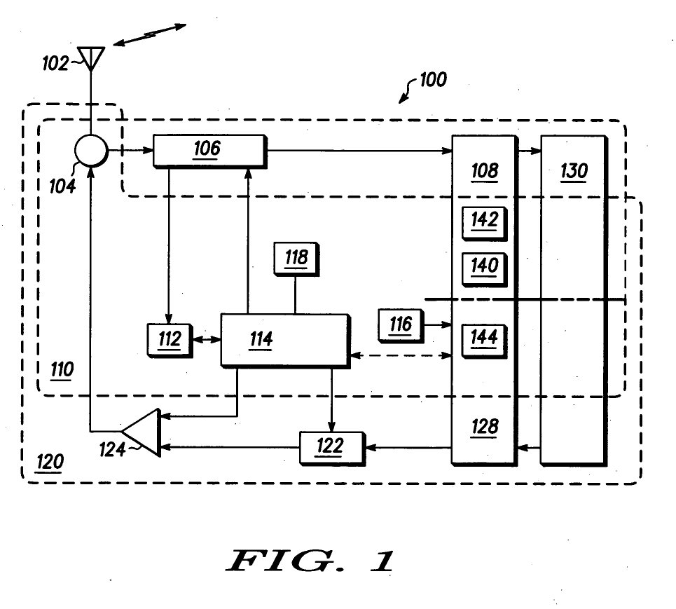

Referring first to FIG. 1, there is shown a block diagram of a wireless subscriber unit 100 adapted to support the inventive concepts of the preferred embodiments of the present invention. Although the preferred embodiment of the present invention is described with reference to a wireless subscriber unit, it is within the contemplation of the present invention that the inventive concepts can be applied equally to other wireless communication units, such as base transceiver stations in cellular-type networks, or devices with wireless Bluetooth™ capabilities, or indeed any other device that has an ability to cause radio frequency interference to other wireless communication units.

The wireless subscriber unit 100 contains an antenna 102 preferably coupled to a duplex filter or antenna switch 104 that provides isolation between a receiver and a transmitter chain within the wireless subscriber unit 100. As known in the art, the receiver chain typically includes receiver front-end circuitry 106 (effectively providing reception, filtering and intermediate or base-band frequency conversion). The front-end circuit is serially coupled to a signal processing function 108. An output from the signal processing function is provided to a user-interface 130, which may comprise a display, speaker, etc.

The receiver chain also includes received signal strength indicator (RSSI) circuitry 112 (shown coupled to the receiver front-end 106, although the RSSI circuitry 112 could be located elsewhere within the receiver chain). The RSSI circuitry is coupled to a controller 114 for maintaining overall subscriber unit control. The controller 114 is also coupled to the receiver front-end circuitry 106 and the signal processing function 108 (generally realised by a DSP).

The controller 114 may therefore receive bit error rate (BER) or frame error rate (FER) data from recovered information. The controller 114 is coupled to the memory device 116 for storing operating regimes, such as decoding/encoding functions and the like. A timer 118 is typically coupled to the controller 114 to control the timing of operations (transmission or reception of time-dependent signals) within the wireless subscriber unit 100.

As regards the transmit chain, this essentially includes user-interface 130 comprising elements such as a microphone, keypad, etc. coupled in series to a transmitter/modulation circuit 122. Thereafter, any transmit signal is passed through a power amplifier 124 to be radiated from the antenna 102. The transmitter/modulation circuitry 122 and the power amplifier 124 are operationally responsive to the controller, with an output from the power amplifier coupled to the duplex filter or antenna switch 104. The transmitter/modulation circuitry 122 and receiver front-end circuitry 106 comprise frequency up-conversion and frequency down-conversion functions (not shown).

In particular, the operation of the signal-processing unit 108 has been adapted to include a resource-responsible agent 140, in order to support the inventive concepts of the preferred embodiments of the present invention. In an enhanced embodiment of the present invention, and advantageously, the wireless subscriber unit 100 may be configured to receive, and react to, a resource-responsible agent from another user in the network (or from a serving BTS in its network). Thereafter, the wireless subscriber unit 100 may transmit the resource-responsible agent 140 to other users in the network, in a ripple-effect manner similar to the distribution of a computer ‘virus’.

In accordance with the preferred embodiment of the present invention, the signal processor 108 of the wireless subscriber unit 100 has been adapted to include an identification function 144, for identifying interference within, or non-availability of a portion of the shared communication resource. In this regard, the identification function 144 may include RSSI measurements noted by RSSI function 112.

The signal processor 108 has also been adapted to include a resource-responsible agent 140. The resource-responsible agent 140 is responsive to an identification of interference, typically received from another subscriber unit that is suffering interference as transmitted by the wireless subscriber unit 100. In addition, the signal processor 108 has been adapted to include a communication adaptation function 142, which is responsive to the resource-responsible agent 140. The communication adaptation function 142 implements any of a number of mechanisms to reduce a level of interference or make a portion of the shared resource available for use. For example, if the suffering communication unit indicates that there is a lack of available communication resource, and the communication unit that receives the resource-responsible agent 140 or an associated trigger is over-utilising the resource, the wireless subscriber unit 100 frees up some of its used resource.

Advantageously, the distribution and/or activation of the resource-responsible agent 140 is effected in response to measured interference (by a communication unit in the same or another communication network) or an indication that a communication unit in the same or another communication network has difficulty accessing a portion of the shared communication resource. Either way, the resource is eventually distributed more fairly.

When the resource-responsible agent software code is passed from a first communication unit to a second communication unit, the second communication unit processes/decodes the software code. In response to the decoding operation, the second communication unit automatically and autonomously re-configures one or more modes of operation/parameters, if it is determined to be operating in a resource irresponsible manner. Dependent upon the prevailing conditions, i.e. whether a wireless subscriber communication unit is suffering from an interference, the wireless subscriber unit may decide to forward the resource-responsible agent 140 to the interferer, or the interferer's network.

In this manner, the signal-processing unit 108, together with respective components within the receiver chain 110, has been adapted to receive and decode a transmission that includes the resource-responsible agent. The resource-responsible agent software code is then stored in the signal-processing unit 108, or another appropriate signal processing unit. The resource-responsible agent software code is then run and, dependent upon the prevailing conditions/operating parameters of the wireless subscriber unit 100, the resource-responsible agent software code influences the operational mode of the wireless subscriber unit 100.

In the communication units that receive the resource-responsible agent, it is envisaged that the degree to which the communication unit automatically and autonomously re-configures one or more of its modes of operation may depend upon prevailing communication conditions, e.g. whether it is suffering or causing interference, and/or on the communication unit's operating parameters. Thus, activation of the resource-responsible agent may have different sensitivity threshold levels, where each level initiates a different operational response within the communication unit.

It is envisaged that the resource-responsible agent may trigger one or more quality of service/performance attributes of the interfering wireless communication unit, to be adapted. For example, the resource-responsible agent 140 may cause one or more of the following effects: a less clear audio and/or video signal, break a connection, fail to establish a connection, perform at a reduced power level or limit a connection time, a reduction in the wireless communication unit's battery power, temporarily disabling the interfering wireless communication unit, increasing a tariff, withholding service, etc.

It is also envisaged that the different re-configuration processes may have a priority associated with the process, such that a higher priority re-configuration process such as reducing a transmit power of the device (and thereby the interference caused by the device), or the power transmitted to the device, is implemented ahead of lower priority processes, such as reducing a frequency of an irregular uploading data to the network, if that uploading process is determined as interfering with another communication unit. A further example is that a quality of service that is offered to the device could be restricted. In this regard, a quality of service is typically described by a set of parameters that specify factors including, maximum bit rate, average bit rate, minimum bit rate, jitter, delay, error rate, priority, service class, etc. Restricting any of these parameters would have the effect of reducing the interference that could arise from operation of the device, either on the maximum level of interference or on the average level of interference over a period of time. Similarly, it is envisaged that a priority for the order in which each of the parameters modified could be set. Alternatively, an algorithmic approach could be used that would reduce a number of the parameters at the same time, to an extent dependent on the interference detected.

In the context of the present invention, when the resource-responsible agent is propagated through a number of communication units, a number of which are configured to run and respond to the code, the resource-responsible agent 140 is able to influence the behaviour of the communication network and in particular the behaviour of specific users in the communication network.

It is envisaged that any of a number of mechanisms can be utilised to run resource-responsible agent software code 140 within the wireless subscriber communication unit 100. For example, mobile execution environment (MeXe) and Java for mobile phones (J2Me) are current examples that can support applications that are able to modify the behaviour of a wireless subscriber communication unit 100 such as a mobile phone. J2Me is a specific version of Java directed towards small computing platforms. MeXe is the mobile execution environment that allows applications running on the phone to execute phone functionality, such as initiation of calls. However, some aspects of the invention described herein may, in some applications, require access to lower level functionality of the communication device. A skilled artisan will appreciate that the inventive concepts herein described are not limited to use in a remote wireless device such as a mobile phone, but may apply to any fixed or wireless device, or combination of devices, operating on the network, such as a BTS or a wireless repeater.

Of course, the various components within the wireless subscriber unit 100 can be arranged in any suitable functional topology able to utilise the inventive concepts of the present invention. Furthermore, the various components within the wireless subscriber unit 100 can be realised in discrete or integrated component form, with an ultimate structure therefore being merely based on general design considerations.

It is within the contemplation of the invention that the use of a resource-responsible agent can be implemented in software, firmware or hardware, with the function being implemented in a software processor (or indeed a digital signal processor (DSP)) being merely a preferred option. In the preferred embodiment of the present invention, the resource-responsible agent 140 is formed of software code, to facilitate ease of distribution throughout the network, for example via over-the-air transmissions. In an alternative embodiment, the resource-responsible agent 140 may be implemented in firmware or hardware and the operation of the resource-responsible agent 140 initiated upon receipt of a ‘trigger’.

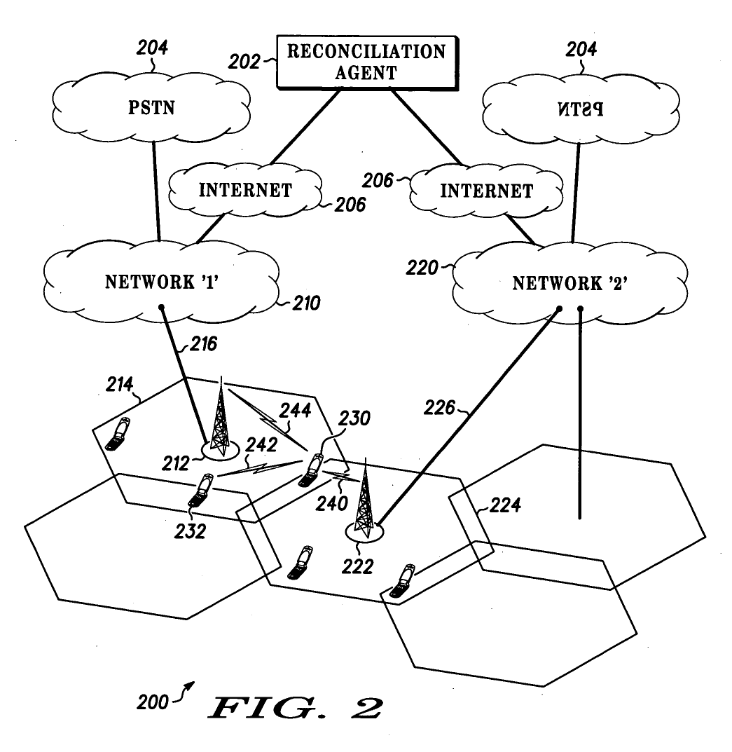

A preferred application of the preferred embodiment of the present invention is in a self organising network, where the network elements have the capability of adjusting their inter-communication links, etc. in an adaptive manner to allow the communications network to function. In particular, the inventive concepts herein described can be applied to a situation where there are two such networks that may be able to evolve individually, but have no way of adjusting respectively their communication habits with respect to each other. For example, their lack of appreciation of the other network's needs could be due to the use of different technologies, or for security reasons when both networks use the same technology, or perhaps even due to the usage patterns of each network being different. An example of such a system is illustrated in the communication system diagram 200 of FIG. 2.

In FIG. 2, a communication system 200 is illustrated having two networks 210, 220, where both networks have respective connections to the public switched telephone network 204 and an access to information database such as the Internet 206. Both networks are supporting communication in a number of communication areas, shown here as wireless communication cells. A first cell 214 includes a first wireless base transceiver station 212 having a fixed connection 216 with the first network 210. A second cell 224 includes a second wireless base transceiver station 222 having a fixed connection 226 with the second network 220.

In accordance with an enhanced embodiment of the present invention, a reconciliation and mediation agent 202 has been included, located preferably somewhere in the Internet 206. The reconciliation and mediation agent 202 is operably coupled to, and mediates between, the two uncoordinated networks 210, 220.

In this embodiment the reconciliation and mediation agent 202 is configured to log the number of communication units (mobile phones in this example) that have activated the resource-responsible agent code in each network. In effect, this provides a proxy for the degree of interference that one system is causing to the other system. The function of the reconciliation and mediation agent 202 is to reconcile the interference that one network causes to the other network and determine whether any countermeasures that either or both networks performed to minimise the interference was satisfactory. Notably, the reconciliation and mediation agent 202 does not need to function in a real-time manner and is not required in all implementations.

The reconciliation and mediation agent 202 may be a server attached to the Internet 206 and not directly part of the first or second networks 210, 220. It is envisaged that the reconciliation and mediation agent 202 may have a service agreement with the networks, whereby it offers a resource-responsible agent service to the network to reduce the net level of interference that each network produces. Advantageously, this configuration could be used by each network to ensure that they are able to meet their respective operational requirements.

The first and second networks 210, 220 are shown as having overlapping coverage areas, which is typical in a wireless cell-based communication system, such that mutual interference occurs between the networks. In accordance with the preferred embodiment of the present invention, the first network 210 and second network 220 encourage their supported wireless communication units to receive and react to any resource-responsible agent that is sent to them.

In a first instance, a wireless communication unit 230 is illustrated as communicating 240 with its serving BTS 222. The wireless communication unit 230 is suffering interference from another BTS, such as BTS 212, and/or other wireless communication units, such as wireless communication unit 232. In this case, wireless communication unit 230 may initiate the distribution of the resource-responsible agent 140 to those communication units that are causing the interference. Alternatively, the wireless communication unit 230 may request that its serving BTS 222 distribute the resource-responsible agent to the interfering BTS(s) to adapt their respective operational parameters and/or to pass on to their respective wireless communication units. In a further alternative embodiment of the present invention, if the communication units have a resource-responsible agent 140 pre-installed, a ‘trigger’ message may be sent to the communication units to activate the resource-responsible agent 140.

It is envisaged that one incentive for the wireless communication units to receive the resource-responsible agent, and react upon it, would be to achieve a greater guarantee of service provision at a given quality level for a period of time. This could be in exchange for, say, accepting a lesser quality of service at other times. It is envisaged that such a flexible quality of service, as individually accepted by the wireless communication units, may be linked to a tariff structure, for example such that a network charges the more resource-responsible wireless communication units a lower tariff.

As indicated previously, it is envisaged that the resource-responsible agent may also be operative in the BTS. In this case, the BTS or wireless communication unit may forward an indication of the current interference scenario, together with the countermeasures performed by the respective communication unit, to the reconciliation and mediation agent 202, so that mediation between the networks can be effected.

In an enhanced embodiment of the present invention, the reconciliation and mediation agent 202 comprises a controllability function to facilitate a higher-level determination of whether networks are behaving fairly. For example, it is envisaged that the controllability function may comprise one or more of the following behaviours:

(i) An ability to report back behaviour and/or countermeasure behaviour of a wireless communication unit or network;

(ii) An ability to trace the progress of the resource-responsible agent strain throughout the networks;

(iii) Specific mutations; the behaviour or counter measure behaviour of a wireless communication unit may be modified in a linear or non-linear manner, depending upon its local environment or information sent from a central point in the network. Specific mutations, in this context, include:
(a) The ability to trigger the operation of the resource-responsible agent of the other party in the communication (propagating the behaviour through the network),
(b) Changes in the operating life of the resource-responsible agent,
(c) Changes in the priority with which various behaviours are initiated (e.g. power reduction, QoS allowed, time restriction, etc.); or
(d) Changes in the algorithm that determines the way in which a multiplicity of changes are made; and

(iv) An ability for the wireless communication unit to time-stamp its activity.

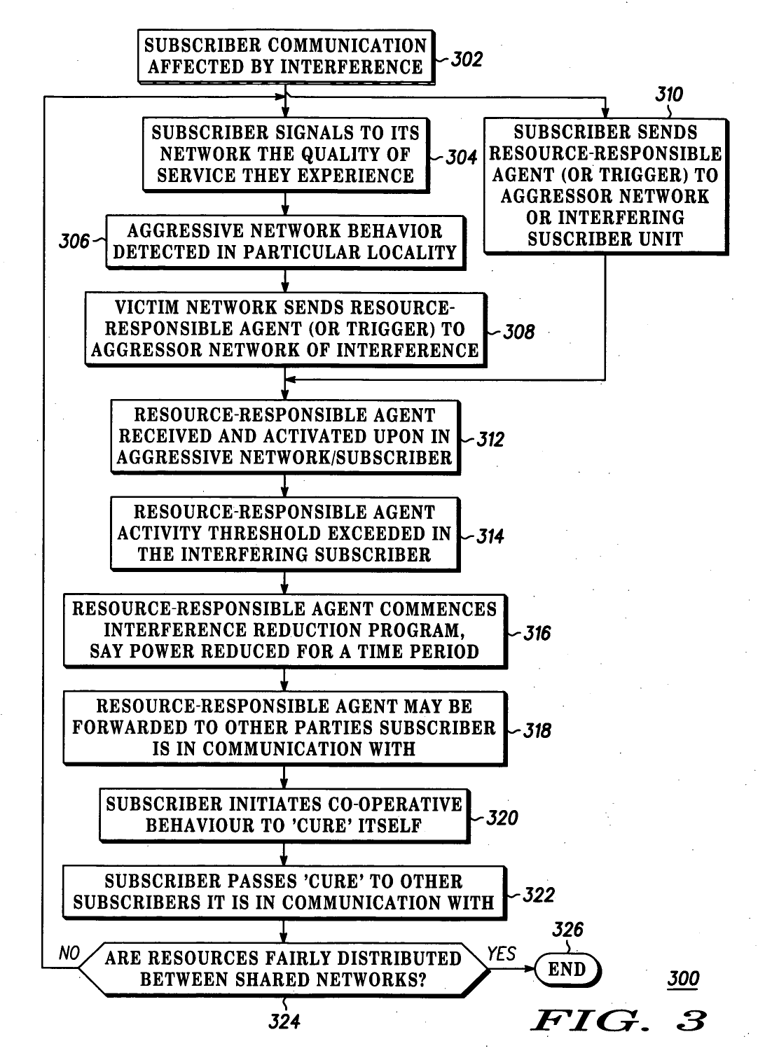

Referring now to FIG. 3, a flowchart 300 illustrates a preferred process for generating, distributing and reacting upon receipt of resource-responsible agent code. Let us first assume that a wireless subscriber communication unit initiates the process, in step 302. Although the preferred process is described with reference to a wireless subscriber communication unit initiating the process, it is envisaged that any communication unit suffering or aware of interference or a lack of available resource may in alternative embodiments, initiate the process.

In a first aspect, the suffering subscriber unit sends a signal to its network indicating the quality of service (or some other metric) that it is experiencing, as shown in step 304. The affected network may then identify aggressive network behaviour from a neighbouring network, according to a geographical area or technology-type or a time of day, etc., as in step 306. The affected network then preferably sends resource-responsible agent code to the aggressive network in step 308. Alternatively, from step 302, the suffering subscriber unit may send resource-responsible agent code direct to the interfering network or the interfering subscriber unit, as shown in step 310. Again, if the communication units are pre-programmed to include resource-responsible agent 140 software code, a ‘trigger’ message may be sent.

In the preferred embodiment, the aggressive network or aggressive subscriber unit receives the resource-responsible agent code and responds accordingly, as shown in step 312. In this regard, the aggressive network or aggressive subscriber unit may determine whether its communication activity exceeds an interference threshold, as in step 314. It is envisaged that the interference threshold may be pre-defined or dynamically adjusted by the subscriber unit or its network.

If the aggressive network or aggressive subscriber unit determines that it needs to, or should, implement an interference reduction or resource release program, in response to the resource-responsible agent code, it does. In this case, performance-affecting properties of the aggressive subscriber communication unit or aggressive network are configured to become active, and adapted accordingly, when triggered by the resource-responsible agent.

In one embodiment, the resource-responsible agent may then, for example, trigger automatically and autonomously an interference reduction or resource release program within the aggressive network or aggressive subscriber unit. For example, the resource-responsible agent may impose one or more time-limited behaviour pattern(s), such as a reduction in transmit power of the aggressive subscriber communication unit or aggressive network, for say a random or fixed period of time, as shown in step 316.

Preferably, in this embodiment, priority levels associated with the interference being caused, or the actions to be taken, may be employed. Such priority levels allow the worse interferers to be addressed first and with harsher penalties. The priority levels may be dynamically revised over time to provide more flexibility in the communication system to adapt to communication trends. In such situations, it is envisaged that the priority levels and/or threshold levels may be updated dynamically according to current needs of the network or wireless communication units.

Similarly, it is envisaged that when the receiving wireless communication unit communicates with any other wireless communication unit in the same or an alternative network, the receiving wireless communication unit would be offered the possibility to forward the resource-responsible agent code (or a ‘trigger’ message) to those other communication units, as shown in step 318. Thus, the mechanism facilitates the propagation of the resource-responsible agent through the network(s), thereby ensuring a fairer share of the available resource and a reduction in the amount of interference observed by the communication units operating within the network(s).

In an enhanced embodiment of the present invention, it is assumed that the resource-responsible agent may act in a similar manner to a computer virus. In such a situation, it is envisaged that all subscriber units receiving and autonomously reacting to a resource-responsible agent in this way may only ‘cure’ themselves of the ‘virus’ by acting in a co-operative and resource-responsible manner, as shown in step 320. Thus, the aggressive communication unit may be able to remove the effect of the resource-responsible agent if they perform, for example, one or more of the following:

(i) Power-down upon sensing interference; (ii) Switch to operating in an opportunity driven multiple access (ODMA) mode;

(iii) Switch to using local short-range nodes to obtain information (thereby reducing usage of more interference generating resources);

(iv) Switch to using a fixed wire-line connection to minimise the wireless communication unit's need to use radio resources;

(v) Halt communications until it is operating nearer to its serving BTS; and/or

(vi) Pay for the privilege of the resource-responsible agent (‘virus’) being disabled.

If it is determined that the resources within the shared networks have been distributed more evenly and/or the levels of interference have been reduced to an acceptable level, in step 322, the process ends in step 324. Otherwise, the process loops to step 304 with a determination by any affected wireless subscriber communication unit (or network) identifying that it is suffering from interference or a lack of a shared resource.

As mentioned above, the distribution and/or activation of a resource-responsible agent may be triggered based on any one or more communication conditions. It is also within the contemplation of the preferred embodiments of the present invention that any wireless communication unit, which is configured to receive and respond to the resource-responsible agent, may react in a number of ways. For example, the wireless communication unit may react differently, in determining what action to take, based on its sensitivity to, or prioritisation allocated to, one or more of the following parameters:

(i) Sensitivity to location; devices in certain locations may have a relatively much greater or lesser impact on mutual interference than in other areas. Also, control of interference in certain areas may be of a much higher or lower priority than in other areas, for example if a performance guarantee is offered in a certain area.

(ii) Sensitivity to frequency; operation on certain frequencies may cause a much greater or lesser potential for causing interference than other frequencies, depending on the proximity of frequency bands. Also, certain bands may have a greater or lesser degree of ownership or licensing for a particular operator.

(iii) Sensitivity to radio frequency transmit power; transmit power is directly linked to the ability cause interference. Thus, it may be more effective to modify the behaviour of the users operating at the highest powers (subject perhaps to the location and frequency of operation).

(iv) Sensitivity to one or more services requested; certain services may be of higher or lesser importance or worth in terms of revenue. Additionally, certain services may cause higher levels to be generated in absolute or average terms.

(v) Sensitivity to event correlations. For example, if a regular or irregular event causes the communication unit in a particular area to experience frequent ‘outages’, the communication unit may, via communication to a BTS or a direct subscriber-to-subscriber connection, forward the resource-responsible agent to the interfering communication units;

(vi) Sensitivity to other parties in any on-going communication. The number of other parties in a communication may vary significantly, for example a conference call could potentially impact a large number of users.

(vii) Sensitivity to any tariffs paid. The goal of an Operator may be to optimise their revenue stream rather than minimise the absolute level of interference, and/or

(viii) Sensitivity to a capability to use other access media, other radio access technologies (RATs) or any opportunity driven multiple access (ODMA) mechanism.

Preferably, this would improve the chance that these interfering units will respond favourably to the resource-responsible agent code and behave in a more resource-responsible manner;

If the network that is causing the interference is unknown to a network that is suffering the interference, it is also within the contemplation of the present invention that the resource-responsible agent may instigate a network detection process, such that the suffering network initiates procedures to detect and inform the aggressive network.

In a yet further enhanced embodiment of the present invention, it is envisaged that the resource-responsible agent may trigger one or more time-random behaviour pattern(s), for example a statistical deterioration of performance by dropping frames, reducing power, etc. In this regard, to accommodate a slow feedback mechanism where the wireless communication unit knows that there is the potential of interference, but not the exact timing of the interference, a random element is introduced into the countermeasure process to soften the need for exact knowledge of the timing of the interference. For example, if the probability that a transmit power level may be permitted in a certain time period could be set to, say, 80%, the countermeasure process would ensure that, for any power level requested in the remaining 20% of the time would be refused.

It is envisaged that there may be a number of resource-responsible agent strains operational within the communication system. In this regard, in contrast to the detrimental impact of a resource-responsible agent strain as described above, a further strain may be configured to, for example, reward a wireless communication unit for responsible behaviour. In this case, a responsible communication unit may be rewarded with a lower tariff or be supported with a more reliable access mechanism or increased priority for services requested by the wireless communication unit, etc.

Similarly, if communication units support the relaying of information from one communication unit to another by an ad-hoc network of links in an ODMA-type scenario, there is a time cost involved. If a user performs some of these ‘public spirited’ activities that impose a cost on them, then it is envisaged that they are likewise rewarded in terms of privileges or costs.

One aspect of the preferred embodiment of the present invention is to propose a set of rules for the receiving wireless communication unit to follow, upon being triggered by, or to activate, the resource-responsible agent. This set of rules is preferably dependent upon the prevailing communication conditions, the performance attributes of the respective communication units, the level and type of interference, etc.

Although the preferred embodiment of the present invention is described with reference to a cell-based wireless communication system, it will be appreciated that the inventive concepts hereinbefore described are equally applicable to any wireless communication system where interference exists between communication units.

A preferred application of an embodiment of the present invention is the identification of rogue wireless communication units, i.e. wireless communication units that have a poor performance and require more resources than other wireless communication units for the same services. Following identification of these rogue units, using the resource-responsible agent, it is envisaged that the performance attributes/operational characteristics of the rogue units are modified so that other users suffer less interference.

It is also within the contemplation of the invention that the resource-responsible agent is used to restrict the capabilities of the wireless communication unit for certain classes of users, e.g. if a denied service was accessed by a user of a given class the properties of the wireless communication unit would change until a 3^{rd} party reset the unit or a sufficiently high class of user registered with/logged on to the wireless communication unit to use it.

Although the preferred embodiment of the present invention is described with regard to interference on a frequency channel, or availability of a frequency resource, it is also within the contemplation of the invention that the resource to be made available could be time slots or time frames in a time division multiple access system or codes in a code division multiple access system.

It will be understood that the communication system, communication unit and method of sharing a communication resource, as described above, provide at least one or more of the following advantages:

(i) The mechanism makes the sharing of communication resources feasible, particularly in an uncoordinated scenario, by dynamically distributing control of the resources to those users whose behaviour is adversely affecting other users, thereby resulting in better utilisation of the available shared communication resource;

(ii) The mechanism provides flexible spectrum sharing and an increase in spectrum efficiency. This may be considered in terms of throughput/MHz/Km2 or revenue/MHz/Km2 or indeed some other way, as will be appreciated by a skilled artisan.

(iii) The mechanism identifies and targets those resource irresponsible users for automatic adjustment of their performance attributes. In this manner, the mechanism can also be used to alter long-term behaviour of subscribers that flagrantly abuse their use of the resource. In effect, the mechanism promotes, and to some degree enforces, ‘co-operative’ behaviour between subscriber communication units, serving communication units (such as BTSs) and/or networks.

(iv) The use of a reconciliation and mediation agent provides more flexibility to dynamically control and adjust the use of resources available to each network or communication unit(s) operating within a shared resource network.

(v) The mechanism of using a readily distributable resource-responsible agent allows decentralized control of a network.

(vi) The resource-responsible agent can be introduced to all subscribers from the start, with ‘responsible’ behaviour placing the agent and its effect on the subscriber's behaviour in remission.

1. A communication system including one or more communication networks supporting communications for a plurality of communication units on a shared communication resource, wherein the communication network comprises:
an identification function for identifying interference within or non-availability of a portion of the shared resource;
a resource-responsible agent, responsive to the identification function identifying an interference within or non-availability of a portion of the shared resource; and
a communication adaptation function, responsive to the resource-responsible agent in reducing a level of interference or making a portion of the shared resource available for use.

2. A communication system according to claim 1, wherein the one or more communication networks comprises a first network generating interference that affects communications on a second network.

3. A communication system according to claim 2, wherein the communication networks are uncoordinated.

4. A communication system according to claim 2, wherein the identification function resides in a subscriber unit or a serving communication unit on the second network.

5. A communication system (200) according to claims 2, wherein the communication adaptation function resides in a subscriber unit or a serving communication unit operating on the first network such that the resource-responsible agent is able to influence the communication of the subscriber unit or the communication behaviour on the first communication network.

6. A communication system according to claim 2, wherein the communication system is further characterised by a reconciliation and mediation agent operably coupled to the first network and second network for mediating therebetween.

7. A communication system according to claim 6, wherein the reconciliation and mediation agent reconciles interference that the first network caused to the second network and determines any countermeasures employed by either network.

8. A communication system according to claim 2, wherein the second network suffering interference from the first network initiates a procedure to detect the interference and inform the first network of the interference.

9. A communication system according to claim 1, wherein the one or more communication networks is a single network, such that the communication adaptation function is responsive to the resource-responsible agent in reducing a level of interference or making a portion of the shared resource available for use within the single network.

10. A communication unit including a processor operating on a shared communication resource, wherein the processor comprises:
a resource-responsible agent, responsive to an identification of interference within or non-availability of a portion of the shared communication resource; and
a communication adaptation function, responsive to the resource-responsible agent in reducing a level of interference caused by the communication unit or making a portion of the shared resource available for use by other communication units.

11. A communication unit according to claim 10, wherein the communication unit is a wireless subscriber communication unit or a wireless serving communication unit.

12. A communication unit according to claim 10, wherein the resource-responsible agent is distributable to a number of communication units operating in the one or more networks.

13. A communication unit according to claim 12, wherein the distribution and/or activation of the resource-responsible agent is based on one or more of the following: location of an interference or communication unit, usage patterns that historically resulted in interference, exchange for receiving a reduced tariff for usage.

14. A communication unit according to claim 10, wherein the communication adaptation function in response to the resource-responsible agent restricts capabilities of an interfering communication unit for certain classes of users.

15. A communication unit according to claim 10, wherein the identification of interference within or non-availability of a portion of the shared communication resource is based on one or more of the following: a local measurement of interference, an interference measurement transmitted to a communication unit via the network or a serving communication unit, an interference measurement transmitted to a communication unit from another communication unit in a similar locality.

16. A communication unit according to claim 10, wherein the communication adaptation function comprises one or more time-limited behaviour pattern(s), including at least one of the group of; a reduction in transmit power of a subscriber communication unit, a network causing interference, for a random period of time, and a network causing interference for a fixed period of time.

17. A communication unit according to claim 10, wherein the communication adaptation function automatically and/or autonomously adapts one or more operational parameters of the communication unit in response to the resource-responsible agent.

18. A communication unit according to claim 10, wherein the communication adaptation function adapts one or more performance attributes of the interfering wireless communication unit causing one or more of the following effects: a less clear audio signal and/or video signal, break a connection, fail to establish a connection, perform at a reduced power level or limit a connection time, a reduction in the wireless communication unit battery power, temporarily disabling the interfering wireless communication unit, increasing a tariff, and withholding service.

19. A communication unit according to claim 10, wherein a communication unit having received a resource-responsible agent is able to remove an effect of the resource-responsible agent if the communication unit performs one or more of the following:
(i) Power-down upon sensing or being informed of interference;
(ii) Switch to operating in an opportunity driven multiple access mode;
(iii) Switch to using local short-range nodes to obtain information;
(iv) Switch to using a fixed wire-line connection;
(v) Halts communications until it is operating nearer to its serving wireless communication unit; and
(vi) Effect a payment for the resource-responsible agent to be disabled.

20. A communication unit according to claim 10, wherein an action taken by the communication adaptation function is based on its sensitivity to, or prioritisation allocated to, one or more of the following parameters:
(i) Location of the wireless communication unit;
(ii) Frequency of operation of the wireless communication unit;
(iii) Radio frequency transmit power of the wireless subscriber communication unit;
(iv) One or more services requested by the wireless subscriber communication unit; and
(v) Event correlations.

21. The communication system according to claim 6, wherein the reconciliation and mediation agent mediates between at least two interfering uncoordinated networks.

22. The communication system according to claim 7, wherein the reconciliation and mediation agent is configured to determine whether any countermeasures that either network has performed has reduced the interference.

23. The communication system according to claim 22, wherein the reconciliation and mediation agent includes a function that controls one or more of the following behaviours:
(i) An ability to report back behaviour and/or countermeasure behaviour employed by a communication unit;
(ii) An ability to trace a progress of a resource-responsible agent strain; and
(iii) An ability for the communication unit to time-stamp its activity.

24. The communication system according to claim 6, wherein the reconciliation and mediation agent is distributable to at least one of a subscriber communication unit and a communication network to effect a modification of the wireless subscriber communication unit's or communication network's operational capabilities in response to a trigger related to potential interference or non-availability of a communication resource.

25. The communication unit according to claim 10 wherein the processor to receive includes a resource-responsible agent operable to modify one or more operational parameters of the communication unit in response to determining that it is operating in a resource irresponsible manner.

26. A method of sharing a communication resource in a communication system including one or more networks supporting communication for a plurality of communication units on the shared communication resource, the method comprising the steps of:
identifying an interference within or non-availability of a portion of the shared resource;
distributing and/or activating a resource-responsible agent to reduce a level of interference or make a portion of the shared resource available for use in the communication system in response to identifying an interference within or non-availability of a portion of the shared resource; and
adapting one or more communication functions upon receipt of activation of the resource-responsible agent.

27. A method of sharing a communication resource in a communication system according to claim 26, wherein the one or more communication networks are uncoordinated and comprises at least a first network generating interference that affects communications on a second network, wherein the method is further comprising the step of:
mediating between the first network and the second network based on any countermeasures employed by either network.

28-29. (canceled)
